(19) United States
(12) Patent Application Publication
(10) Pub. No.: US 2024/0284806 A1
(43) Pub. Date: Aug. 22, 2024

(54) SEMICONDUCTOR DEVICE HAVING AN ELECTROSTATICALLY-BOUNDED ACTIVE REGION

(71) Applicant: Microsoft Technology Licensing, LLC, Redmond, WA (US)

(72) Inventors: Gijsbertus de Lange, Redmond, WA (US); Pavel Aseev, Redmond, WA (US); Sebastian Heedt, Redmond, WA (US)

(73) Assignee: Microsoft Technology Licensing, LLC, Redmond, WA (US)

(21) Appl. No.: 18/568,635

(22) PCT Filed: Jun. 29, 2021
(86) PCT No.: PCT/EP2021/067876

§ 371 Date: Dec. 8, 2023

(51) Int. Cl. H10N 60/10; H10N 60/01; H10N 60/83

(52) U.S. Cl. CPC H10N 60/128; H10N 60/01; H10N 60/83

(57) ABSTRACT

Described is a semiconductor device comprising a substrate having a surface; a mesa arranged on the surface of the substrate, the mesa having a perimeter; and one or more gate electrodes. The mesa is obtainable by selective area growth, and comprises a semiconductor heterostructure for hosting a 2-dimensional electron gas or a 2-dimensional hole gas. The one or more gate electrodes are configured to deplete electrically portions of the semiconductor heterostructure to define a boundary of an active region of the semiconductor heterostructure, the boundary being spaced from the perimeter of the mesa. By using a selective-area-grown mesa and defining the boundary of the active region electrostatically, improved electronic properties may be obtained, for example by avoiding the diffuse scattering of charge carriers. Also provided is a method for fabricating the device, and a use of one or more gate electrodes to define an active region of a semiconductor component.

### BACKGROUND

Topological quantum computing is based on the phenomenon whereby non-abelian anyons, in the form of “Majorana zero modes” (MZMs), can be formed in regions where a semiconductor is coupled to a superconductor. A non-abelian anyon is a type of quasiparticle, meaning not a particle per se, but an excitation in an electron liquid that behaves at least partially like a particle. An MZM is a particular bound state of such quasiparticles.

Under certain conditions, MZMs can be formed close to an interface between a semiconductor and superconductor. For example, MZMs may be formed in a device comprising a semiconductor nanowire coated with a superconductor. A nanowire has a length which is many times greater than its diameter and can be considered as a 1-dimensional system. MZMs can also be formed in two-dimensional systems, comprising a superconductor coupled to a quantum well hosting a 2-dimensional electron gas, such as described by Suominen et al, Phys. Rev. Lett. 119, 176805 (2017) and Nichele et al, Phys. Rev. Lett. 119, 136803 (2017).

When MZMs are induced in a structure, the structure is said to be in the “topological regime”. To induce this requires a magnetic field, conventionally applied externally, and also cooling of the structure to a temperature that induces superconducting behaviour in the superconductor material.

Topological devices are useful for creating a quantum bit which can be manipulated for the purpose of quantum computing. A quantum bit, also referred to as a qubit, is an element upon which a measurement with two possible outcomes can be performed, but which at any given time (when not being measured) can in fact be in a quantum superposition of the two states corresponding to the different outcomes.

To induce MZMs, the device is cooled to a temperature where the superconductor (e.g. aluminium) exhibits superconducting behaviour. The superconductor causes a proximity effect in the adjacent semiconductor, whereby a region of the semiconductor near the interface with the superconductor also exhibits superconducting properties. I.e. a topological phase behaviour is induced in the adjacent semiconductor as well as the superconductor. It is in this region of the semiconductor where the MZMs are formed.

Another condition for inducing the topological phase where MZMs can form is the application of a magnetic field in order to lift the spin degeneracy in the semiconductor. Degeneracy in the context of a quantum system refers to the case where different quantum states have the same energy level. Lifting the degeneracy means causing such states to adopt different energy levels. Spin degeneracy refers to the case where different spin states have the same energy level. Spin degeneracy can be lifted by means of a magnetic field, causing an energy level spilt between the differently spin-polarized electrons. This is known as the Zeeman effect. Typically, the magnetic field is applied by an external electromagnet.

### SUMMARY

In one aspect, the present invention provides a semiconductor device. The semiconductor device comprises a substrate having a surface; a mesa arranged on the surface of the substrate, the mesa having a perimeter; and one or more gate electrodes. The mesa is obtainable by selective area growth and comprises a semiconductor heterostructure for hosting a 2-dimensional electron gas or a 2-dimensional hole gas. The one or more gate electrodes are configured to deplete electrically portions of the semiconductor heterostructure to define a boundary of an active region of the semiconductor heterostructure, the boundary being spaced from the perimeter of the mesa.

In another aspect, the present invention provides a method of fabricating a semiconductor device. The method comprises: growing a mesa on a surface of a substrate by selective area growth, the mesa comprising a semiconductor heterostructure suitable for hosting a 2-dimensional electron gas or a 2-dimensional hole gas; and subsequently fabricating one or more gate electrodes. The one or more gate electrodes are configured, when in use, to deplete electrically portions of the semiconductor heterostructure to define a boundary of an active region of the semiconductor heterostructure, the boundary being spaced from a perimeter of the mesa.

In a still further aspect, the present invention provides the use of one or more gate electrodes to define an active region of a semiconductor component by depleting electrically a boundary of the active region, wherein the semiconductor component is obtainable by selective area growth, and wherein the boundary is spaced from an edge of the semiconductor component.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Nor is the claimed subject matter limited to implementations that solve any or all of the disadvantages noted herein.

### BRIEF DESCRIPTION OF THE DRAWINGS

To assist understanding of embodiments of the present disclosure and to show how such embodiments may be put into effect, reference is made, by way of example only, to the accompanying drawings in which:

FIG. 1 is a schematic cross-section of a first example of a semiconductor device;

FIG. 2 is a schematic plan view of a second example of a semiconductor device;

FIG. 3a is a schematic plan view of a third example of a semiconductor device;

FIG. 3b is a schematic cross-section of the FIG. 3a device;

FIG. 4 is a schematic plan view of a fourth example of a semiconductor device;

FIG. 5 is a scanning electron microscopy, SEM, micrograph of a semiconductor heterostructure on a substrate;

FIG. 6 is a transmission electron microscopy, TEM, micrograph taken along a part of line A . . . A of FIG. 5;

FIG. 7 is an elemental map showing the distribution of gallium in a semiconductor component comprising indium gallium arsenide;

FIG. 8 is a flowchart outlining a method of fabricating a semiconductor device; and

FIG. 9 is a flowchart outlining a method of operating a semiconductor device.

### DETAILED DESCRIPTION OF EMBODIMENTS

As used herein, the verb ‘to comprise’ is used as shorthand for ‘to include or to consist of’. In other words, although the verb ‘to comprise’ is intended to be an open term, the replacement of this term with the closed term ‘to consist of’ is explicitly contemplated, particularly where used in connection with chemical compositions.

Directional terms such as “top”, “bottom”, “left”, “right”, “above”, “below”, “horizontal” and “vertical” are used herein for convenience of description, with the substrate being taken to be at the “bottom” of the device. For the avoidance of any doubt, this terminology is not intended to limit the orientation of the device in an external frame of reference.

The abbreviation “2DEG” refers to a 2-dimensional electron gas. “2DHG” refers to a 2-dimensional hole gas.

The term “superconductor” refers to a material which becomes superconductive when cooled to a temperature below a critical temperature, Tc, of the material. The use of this term is not intended to limit the temperature of the device.

A “semiconductor-superconductor hybrid structure” comprises a semiconductor component and a superconductor component which may become coupled to one another under certain operating conditions. In particular, this term refers to a structure capable of showing topological behaviour such as Majorana zero modes, or other excitations useful for quantum computing applications. The operating conditions generally comprise cooling the structure to a temperature below the critical temperature, Tc, of the superconductor component, applying a magnetic field to the structure, and applying electrostatic gating to the structure. Generally, at least part of the semiconductor component is in intimate contact with the superconductor component, for example the superconductor component may be epitaxially grown on the semiconductor component. Certain device structures having one or more further components between the semiconductor component and superconductor component have however been proposed.

A comparative technique for forming a semiconductor heterostructure comprises growing a stack of layers of semiconductor which each cover the entire surface of a substrate, and then etching the layers to a desired shape. A substrate may have a surface area of several square centimetres. When using this comparative technique, very good lattice matching between adjacent layers of materials is essential for obtaining crystals of adequate quality. In other words, adjacent materials must have lattice constants which are approximately equal. This constrains the combinations of materials which can be used.

Another limitation of the comparative technique, when applied to the fabrication of hybrid devices, is related to faceting. Generally, high-quality planar semiconductor layers are grown on {001} crystal facets due to favourable growth kinetics of facet formation.

However, the highest-quality superconductors are grown on {111} facets. For hybrid devices, there is a desire to grow high quality semiconductors on {111} facets. In case of selective-area growth, the growth kinetics are significantly different, allowing the growth of high-quality semiconductors on {111} facets, which in turn results in higher quality hybrid devices.

Provided herein is a semiconductor device which is configured to allow for the use of a wider range of combinations of materials, and which can be fabricated on a broader range of crystal faces while having good electronic performance.

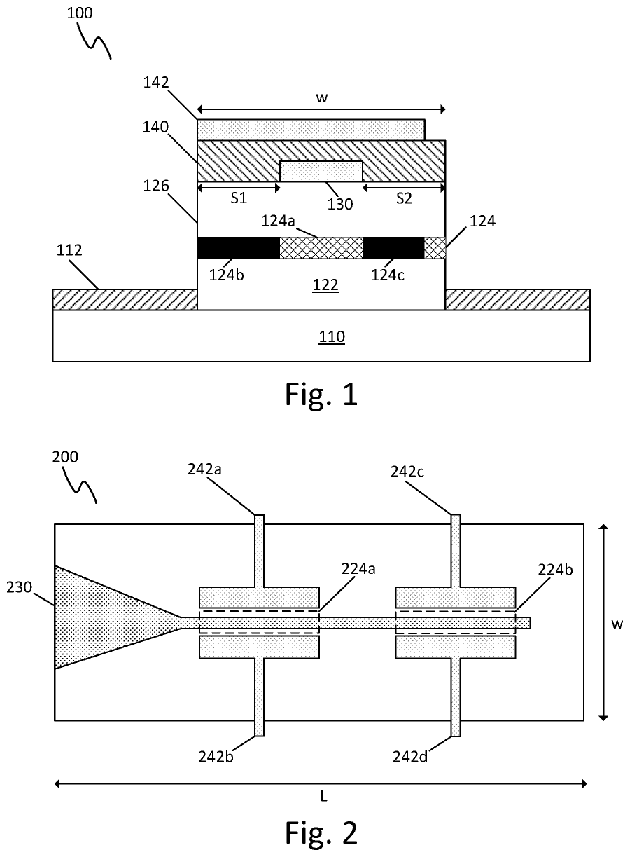

A first example of a semiconductor device 100 is illustrated in cross-section in FIG. 1. The example device 100 is a semiconductor-superconductor hybrid device. The example device 100 may be useful as a component of a topological qubit.

The example device includes a semiconductor heterostructure 122, 124, 126. The semiconductor heterostructure is in the form of a mesa which extends from the surface of a substrate 110.

The substrate 110 provides a base on which the semiconductor heterostructure 122, 124, 126 is grown. The substrate 110 typically comprises a wafer, i.e. a piece of single crystalline material. One example wafer material is indium phosphide. Other examples of wafer materials include gallium arsenide, indium antimonide, indium arsenide, and silicon. The substrate may be a more elaborate workpiece, further comprising additional structures arranged on or over the wafer. The substrate may include layers of two or more materials.

The substrate may have a {111} crystal face. The top of the mesa may therefore also have a {111} crystal face. This may be useful in implementations where a superconductor component is to be formed on the mesa, because superconductors such as lead and aluminium grow best on {111} facets.

The semiconductor heterostructure comprises a lower barrier 122 arranged epitaxially on the substrate 110; a quantum well 124 arranged epitaxially on the lower barrier 122; and an upper barrier layer 126 arranged epitaxially on the quantum well 124. This structure is referred to as a heterostructure because the quantum well comprises a material which is different from the material(s) of the lower barrier and upper barrier. The materials of the lower barrier layer and the upper barrier layer may each be independently selected.

The lower barrier 122, quantum well 124, and upper barrier 126 are each in the form of layers. It will be appreciated that overgrowth may occur at edges of the mesa. For example, the upper barrier 126 may wrap around the edge of the mesa.

Quantum well 124 may comprise a layer of semiconductor material which has a relatively small band gap compared to the materials of the lower and upper barriers 122, 126. Illustrative materials useful for forming quantum wells are described in, for example, Odoh and Njapba, “A Review of Semiconductor Quantum Well Devices”, Advances in Physics Theories and Applications, vol. 46, 2015, pp. 26-32; and S. Kasap, P. Capper (Eds.), “Springer Handbook of Electronic and Photonic Materials”, DOI 10.1007/978-3-319-48933-9_40.

The quantum well 124 is typically a few atomic layers thick. For example, the quantum well 124 may have a thickness in the range 2 to 7 nm.

The configuration of the upper and lower barriers is not particularly limited provided that a 2-dimensional electron gas (“2DEG”) or a 2-dimensional hole gas (“2DHG”) can be formed in the quantum well layer. The lower barrier may comprise one or more layers of one or more different materials. The upper barrier may comprise one or more layers of one or more different materials. Constructing a barrier from a plurality of layers may provide defect filtering, i.e. may reduce the effects of dislocations in the crystalline structure of the materials used.

In use, a 2DEG or 2DHG is formed in the quantum well layer 124, and more specifically in an active region 124a, which will be discussed in more detail below. Excitations of interest, such as Majorana zero modes, may be induced in the 2DEG. The upper and lower barriers serve as insulating components for localising charge in the quantum well 124.

The semiconductor heterostructures provided herein are fabricated by selective area growth. Selective area growth involves forming an amorphous mask on the substrate, and then growing the semiconductor heterostructure in openings in the mask. In other words, an amorphous mask is used to control the location at which the semiconductor heterostructure grows. The amorphous mask 112 typically remains in the finished device and surrounds the bottom part of the mesa.

Efficient strain relaxation may take place during growth at the perimeter of the selective area grown structure. Differences between the lattice constants of adjacent materials are therefore well-tolerated. Consequently, a very wide range of combinations of different materials may be used.

The relaxation of strain is particularly efficient when the mesa has a width w which is relatively small. Typically, the width w of the mesa is less than or equal to 2 μm, and more preferably less than or equal to 1 μm.

It has been found that strain relaxation results in inhomogeneity in the semiconductor materials in areas close to the edge of the mesa. The stoichiometry of the semiconductor material may vary. The thickness of the quantum well may vary. Inhomogeneity can degrade the material's charge transport properties, for example by causing diffuse scattering of electrons in the case of a structure which hosts a 2DEG, or holes in the case of a structure which hosts a 2DHG. In regions away from the perimeter, the materials have good homogeneity.

By defining the boundaries of the active region 124a electrostatically, rather than relying on a material boundary, the effects of inhomogeneity can be avoided. In the present example, the boundaries of active region 124a are defined by using a gate stack 140, 142 in conjunction with a superconductor component 130 which shields the active region 124a from an electrostatic field applied by the gate stack.

The superconductor component 130 is arranged on the upper barrier 126. The edges of the superconductor component 130 are spaced from the edges of the mesa by distances S1, S2. The superconductor component may be configured to undergo energy level hybridisation with the semiconductor material of the quantum well. In other words, the device may be a semiconductor-superconductor hybrid device. The upper barrier layer 126 may serve to adjust the strength of the interaction between the superconductor component 130 and the quantum well layer 124, as described in US 2021/0126181 A1.

The nature of the superconductor is not particularly limited and may be selected as appropriate. The superconductor is typically an s-wave superconductor. Any of the various s-wave superconductors known in the art may be used. Examples include aluminium, indium, tin, and lead, with aluminium being preferred in some contexts. In implementations where aluminium is used, the superconductor component may for example have a thickness in the range 3 to 20 nm.

The gate stack is arranged over the mesa and comprises a gate dielectric 140 and a gate electrode 142 arranged on the gate dielectric 140. The gate dielectric serves to prevent the flow of current between the gate electrode 142 and the superconductor component 130. The gate dielectric 140 also prevents the flow of current between the gate electrode 142 and the semiconductor heterostructure 122, 124, 126.

In operation, the gate electrode 142 is used to apply an electrostatic field which electrically depletes regions 124b, 124c of the quantum well layer 142, thereby defining the boundaries of an active region 124a. Gate electrode 142 may be referred to as a “depletion gate”. The active region 124a is not depleted.

In this example, superconductor component 130 screens the active region 124a from the electrostatic field. Alternatively, the gate electrode may be configured so as not to extend over the active region 124a.

As will be appreciated, if the semiconductor heterostructure hosts a 2DEG then the voltage applied to the gate electrode 142 will be a negative voltage; and if the semiconductor heterostructure hosts a 2DHG then the voltage applied to the gate electrode 142 will be a positive voltage.

The active region 124a is, in effect, electrically isolated from the perimeter region of the device by the depleted regions 124b, 124c. Material in the perimeter region, which is less homogeneous than material toward the middle of the mesa, is not therefore used as the active part of the device. This may improve electrical performance, e.g. by avoiding diffuse scattering of charge carriers.

The configuration of the depleted regions is not particularly limited, provided that the active region is isolated from the inhomogeneous material at the edges of the mesa. It has been found that inhomogeneous regions created by strain relaxation have a relatively small spatial extent. The spacing between the perimeter of the mesa and the edge of the active region 124a may be, for example, at least 10 nm, optionally in the range 10 to 200 nm, further optionally in the range 100 to 200 nm. A depleted region may extend up to the perimeter of the mesa, as illustrated by depleted region 124b. Alternatively, a depleted region may be between the active region 124a and the perimeter of the mesa, without necessarily extending all the way to the perimeter, as illustrated by the depleted region 124c.

A second example of a semiconductor device 200 will now be explained with reference to FIG. 2. FIG. 2 shows a plan view of the device.

Like the FIG. 1 device, the FIG. 2 device comprises a semiconductor heterostructure in the form of a selective-area-grown mesa arranged on a substrate. The example mesa is rectangular in plan. The mesa is narrow, typically having a width of less than or equal to 2 μm, to allow strain relaxation during growth of the crystalline layers of the mesa. The length L of the mesa is not particularly limited, and may be many times larger than its width w.

A superconductor component 230 is arranged on the top surface of the mesa. The superconductor component 230 includes a contact pad area at one end, and an elongate portion which extends in the length direction L of the mesa. The contact pad is for connecting the superconductor component to further components, for example via a wire bond. A superconductor component may include more than one contact pad. For example, there may be contact pads at two ends of the superconductor component.

The FIG. 2 device differs from the FIG. 1 device in terms of the configuration of the gate electrodes. The device 200 includes a plurality of depletion gates 242a, 242b, 242c, and 242d.

The depletion gates include a first pair of gate electrodes 242a, 242b which is configured to define the boundary of a first active region 224a. A second pair of gate electrodes 242c, 242d is configured to define the boundary of a second active region 224b. The boundaries are defined by applying a voltage to the gate electrodes, in order to deplete electrically the quantum well in the areas underneath the electrodes. The active regions 224 of the quantum well are under the superconductor component.

The devices provided herein may include any number of active regions, each defined by any number of gate electrode as desired.

In the illustrated example, the two active regions 224 are spaced from one another. The spacing provides a junction between the active regions. Such a junction may serve various purposes. For example, a further electrode may be provided for injecting electrodes at the junction.

In this example, the gate electrodes 242 do not extend over the superconductor component 230. This may, in some implementations, allow the gate dielectric as illustrated in FIG. 1 to be omitted: the upper barrier of the semiconductor heterostructure may function to prevent flow of current from the gate electrodes to the active region of the quantum well. Typically, a gate dielectric is present between the gate electrodes 242 and upper barrier of the semiconductor heterostructure since the inclusion of a gate dielectric may more effectively prevent the flow of current between the gate electrodes and the quantum well.

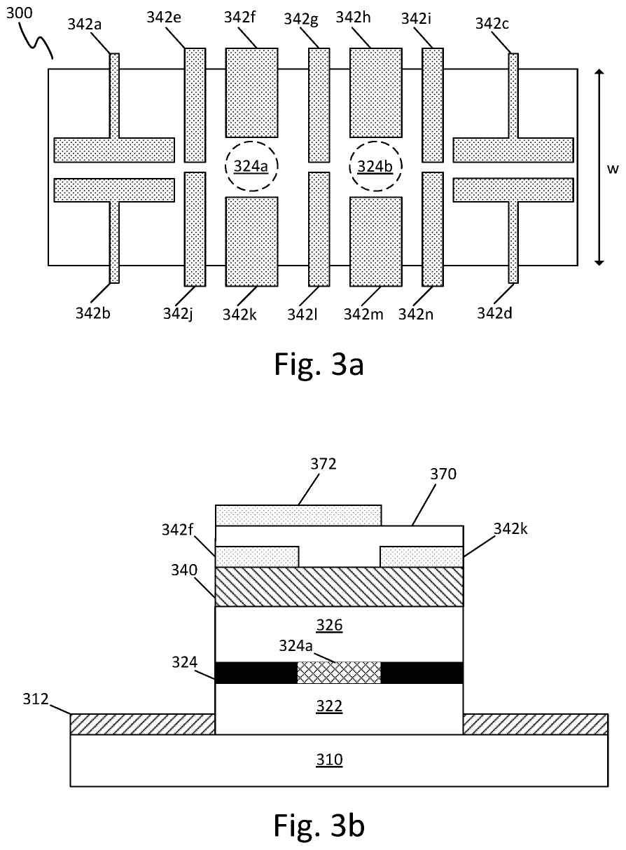

A third example device 300 is illustrated in plan in FIG. 3a, and a cross-section is shown in FIG. 3b. The device of FIGS. 3a and 3b may be useful as a component of a spin qubit device or a high-mobility field-effect transistor.

Like the FIG. 1 and FIG. 2 devices, example device 300 is arranged on a substrate 310 and includes a mesa comprising a semiconductor heterostructure 322, 324, 326. The mesa is as previously described and has a narrow width w, e.g. a width of less than or equal to 2 μm. The mesa is selective-area-grown and is surrounded by a mask 312.

The device 300 further includes a plurality of depletion gate electrodes 342 arranged over the top surface of the mesa for defining boundaries of active regions of the device. An optional dielectric 340 is arranged between the depletion gates 342 and the upper barrier 326 of the semiconductor heterostructure.

At one end of the mesa, the device includes a pair of depletion gates 342a, 342b. A further pair of depletion gates 342c, 342d is arranged at an opposite end of the mesa. Depletion gates 342a, 342b, 342c, 342d are as described with reference to electrodes 242 of the FIG. 2 device.

The device includes further depletion gates 342e to 342n which, when in use, define the perimeters of two active regions 324a, 324b by depleting charge carriers from portions of the semiconductor heterostructure. The perimeter of first active region 324a is defined by electrodes 342e, 342f, 342g, 342j, 342k, and 324l. The perimeter of second active region 324b is defined by electrodes 342g, 342h, 342i, 4321, 342m, and 342n. The active regions 324a, 324b are in the form of quantum dots.

As shown in FIG. 3b, the device of this example includes a further dielectric 370 arranged over the depletion gates, and an additional electrode 372 arranged over the further dielectric 370. In this example, the additional electrode overlaps depletion gate 342f and also extends over the first active region 324a. Since the additional electrode 372 extends over the active region, the additional electrode 372 is useful for gating the active region. This illustrates that the devices provided herein may include further electrodes in addition to the depletion gates.

In order to use quantum dots to implement a spin qubit, a magnetic field is needed to lift spin degeneracy. The device may include one or more ferromagnetic components for applying a magnetic field to the quantum dots.

For example, one or more of the gate electrodes which define the perimeters of the quantum dots may comprise a ferromagnetic material, for example cobalt. In such implementations, the one or more gate electrodes may act as the ferromagnetic component.

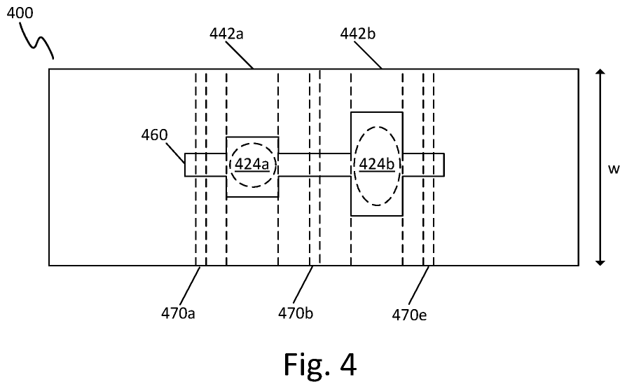

Alternatively or additionally, the device may further comprise a ferromagnetic component which is not a gate electrode. This is illustrated in FIG. 4, which shows a schematic plan view of a device 400. Device 400 differs from device 300 by including a dedicated ferromagnet, and by using a different arrangement of gate electrodes to define each quantum dot.

The device 400 includes a semiconductor heterostructure as previously described with reference to FIGS. 1 to 3.

Device 400 further includes a ferromagnet 460. The ferromagnet 460 has a shape which is selected to apply a magnetic field to active quantum dot regions 424a, 424b of the device. The ferromagnet 460 of this example comprises a ferromagnetic metal, for example cobalt.

In devices which include a plurality of active regions, it may be useful to apply individually-selected magnetic fields to individual ones of the active regions. For example, to implement a spin qubit it may be necessary to apply an inhomogeneous magnetic field over two or more quantum dots. In this example, the portion of the ferromagnet 460 which is aligned with the first quantum dot region 424a has a smaller width than the portion of the ferromagnet 460 which is aligned with the second quantum dot region 424b. The two quantum dot regions therefore experience different magnetic fields.

Gate electrodes 442a, 442b in the form of strips extend over parts of the ferromagnet 460. The gate electrodes 442a, 442b provide confinement of charge carriers in the width direction, i.e. define the lateral boundaries of the quantum dots 424a, 424b. The gate electrodes 442a, 442b are separated from the ferromagnet 460 by a dielectric. The dielectric may be as described with reference to dielectric 140 of the FIG. 1 device.

Since the gate electrodes 442a, 442b extend over the ferromagnet, and the ferromagnet of this example comprises a ferromagnetic metal, the ferromagnet 460 shields the regions of the semiconductor component which are under the ferromagnet from the electrostatic field applied by the gate electrodes 442a, 442b. These shielded regions are the active regions of the device 400. Ferromagnet 460 also applies a magnetic field to the active regions.

In alternative implementations where the gate electrodes do not extend over the active region, the ferromagnet may comprise a ferromagnetic insulator material.

The example device 400 further includes tunnel gates 470a, 470b, 470c. Pairs of tunnel gates define the boundaries of the quantum dots 424a, 424b in the longitudinal direction. The lateral boundaries of first quantum dot 424a are defined by tunnel gates 470a and 470b. The lateral boundaries of the second quantum dot 424b are defined by tunnel gates 470b and 470c. Tunnel gates may also be useful for controlling the operation of the device.

In the illustrated example, the tunnel gates 470a, 470b, 470c overlap the ferromagnet 460. In the region of the overlap, the ferromagnet 460 has a relatively narrow width. The width of the ferromagnet in the region of the overlap is selected to allow for partial depletion of charge carriers from the quantum well underneath the ferromagnet when an operating voltage is applied to the tunnel gate. Conductivity in these regions may be suppressed by applying the operating voltage, thereby forming tunnel barriers. In variants, the tunnel barriers may be omitted. In such variants, the ferromagnet may be arranged only over the active regions of the device.

It will be appreciated that example devices 300 and 400 do not include a superconductor component configured to undergo energy level hybridisation with the quantum well of the semiconductor heterostructure. In other words, example devices 300 and 400 are not topological devices. This illustrates that the concepts provided herein may be applied to devices which are not necessarily semiconductor-superconductor hybrid devices.

Various modifications may be made to the illustrated devices.

The shapes of the gate electrodes are not particularly limited, provided that the gate electrodes are operable to define the boundaries of the active regions of the semiconductor heterostructure. Gate electrodes may include linear portions and/or curved portions, in any desired configuration.

The number of depletion gates is not particularly limited. Any given active region may be defined by a single gate electrode, or by a plurality of gate electrodes.

The devices may include any number of further electrodes for performing further functions. Further electrodes may be fabricated at the same time as the depletion gates, in other words may be arranged in the same layer as the depletion gates. The inclusion of such further gates is optional.

Alternatively or additionally, a dielectric may be provided over the depletion gates and further electrodes may be arranged on the dielectric. In other words, the device may include a further layer of electrodes. In such implementations, the further electrodes may overlap the depletion electrodes and may be separated from the depletion electrodes by the dielectric.

Where present, the further electrodes may, for example, comprise electrodes for gating the active region of the device.

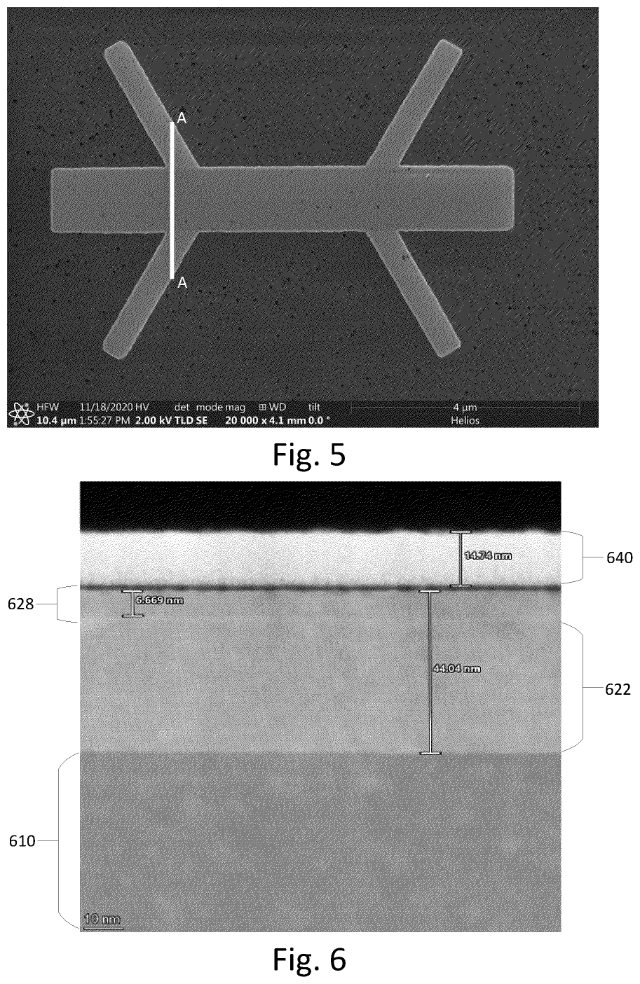

The shape of the mesa is also not particularly limited. The illustrated mesas are rectangular in plan, however other shapes are possible since selective area growth allows mesas of arbitrary shapes to be fabricated. For example, the mesa may have a branched structure. Electrodes may be arranged on the branches. One such branched structure is illustrated in the scanning electron microscopy image shown in FIG. 5.

The width of the mesa may be defined as the length of the shortest line which passes from a point on the perimeter of the mesa, through the active region, and to another point on the perimeter of the mesa. The width is measured parallel to the surface of the substrate. In areas away from the active region, the mesa may have any shape.

The illustrated examples show gate electrodes which are arranged on top of the mesa, in other words, the devices are top-gated. Other variants may be side-gated, having a gate stack arranged on the side walls of the mesa. As will be appreciated, the depth to which a semiconductor is depleted varies depending on the applied gating voltage. An operating voltage of the gate electrodes may be selected so as to deplete selectively the edges of the quantum well layer. Bottom-gated devices are also contemplated.

Devices may include any number of additional electrodes, which may provide a variety of functions. Examples of additional electrodes include electrodes for selectively gating the active region; electrodes for injecting electrons into the active region; electrodes for receiving electrons from the active region; and electrodes for connecting one or more portions of the device to one or more further devices. Such additional electrodes may be present in any appropriate combination.

In particular, the active region may be configured to operate as a channel of a field-effect transistor, by providing source and drain electrodes at respective ends of the active region. The one or more gate electrodes which define the boundaries of the active region may be operable to gate the channel, by varying the voltage applied to the gate electrodes. The gate electrodes may deplete the active region when operated at a voltage having a large magnitude. Alternatively, a separate gate electrode for gating the channel may be provided. In particular, a device of the type shown in FIG. 2 may be configured as a field-effect transistor.

The devices provided herein may be incorporated into circuits and may be coupled to further components. For example, a device may be in communication with an amplifier circuit for allowing readout of signals from the device.

In devices which include a ferromagnet, the upper barrier of the semiconductor heterostructure may prevent flow of current between the quantum well and the ferromagnet 460. An additional dielectric may optionally be arranged between the ferromagnet and the upper barrier. The additional dielectric may comprise a layer of a material selected from, for example, silicon oxides, SiOₓ; silicon nitrites, SiNₓ; aluminium oxides, AlOₓ; and hafnium oxides, HfOₓ.

In devices which include a ferromagnetic component, the ferromagnetic component is not necessarily configured to shield an active region of the device from an applied electrostatic field. In such implementations, the one or more gate electrodes do not extend over the active region. This may allow the ferromagnet to be formed from a ferromagnetic insulator material, for example a material selected from EuS, EuO, GdN, Y₃Fe₅O₁₂, Bi₃Fe₅O₁₂, YFeO₃, Fe₂O₃, Fe₃O₄, Sr₂CrReO₆, CrBr₃/CrI₃, and YTiO₃.

The FIG. 4 example includes a single ferromagnet. Devices which include two or more ferromagnets are also contemplated. For example, individual active regions may be associated with respective individual ferromagnetic components.

One or more further components may be arranged on the surface of the substrate. For example, the substrate may have one or more shadow walls arranged thereon. Shadow walls are useful during fabrication of devices for controlling the deposition of materials. In particular, shadow walls may allow the controlled deposition of metal components such as superconductor components and electrodes. This may allow metal components of controlled shapes to be fabricated without the use of etching. Avoiding etching may help to avoid damage to the semiconductor portions of the device, and/or may allow for better interfaces between components. Shadow walls and their uses are discussed in detail in, for example, US 2020/0243742 A1.

The nature of the semiconductor heterostructure is not particularly limited. One illustrative example will now be described with reference to FIG. 6. FIG. 6 is a transmission electron microscopy, TEM, micrograph taken along a part of line A . . . A of FIG. 5.

The heterostructure is arranged on a substrate 610, which in this example comprised indium phosphide. A lower barrier 622 in the form of a layer of indium gallium arsenide is arranged on the substrate. A quantum well comprising a layer of indium arsenide and an upper barrier comprising a layer of indium gallium arsenide are arranged on the lower barrier. The quantum well and upper barrier together are labelled as 628. The upper barrier is covered by a layer of native oxide, visible as a dark stripe in the TEM micrograph. The native oxide layer of the upper barrier is covered by a layer of dielectric 640, which in this example comprises hafnium oxide, HfOₓ.

The approximate thicknesses of the lower barrier, quantum well, and upper barrier are 35 nm, 2 nm and 7 nm, respectively.

It will be appreciated that layer thicknesses may be selected as appropriate, and that many other combinations of materials are possible.

The heterostructure may comprise III-V semiconductor materials. The III-V semiconductor materials may be compounds or alloys each comprising at least one group III element selected from indium, aluminium and gallium; and at least one group V element selected from arsenic, phosphorous, and antimony. The materials of the heterostructure may, for example, each independently comprise materials of Formula 1:

AlₓIn_{y}Ga_{z}As

wherein values of x, y and z are independently selected, and are the range 0 to 1. x, y and z may sum to 1. Examples of particularly useful materials include: indium arsenide, aluminium indium arsenide, indium gallium arsenide, aluminium gallium arsenide, and aluminium indium gallium arsenide. As will be appreciated, electronic properties of the materials of the heterostructure may be controlled by varying their composition and stoichiometry. Typically, when the heterostructure comprises materials of Formula 1, the heterostructure will host a 2DEG.

The use of other classes of semiconductor materials is also contemplated. For example, the heterostructure may comprise II-VI semiconductor materials. Examples of II-VI semiconductor materials include cadmium telluride, mercury telluride, lead telluride and tin telluride. The heterostructure may comprise group IV semiconductor materials. For example, the heterostructure may comprise silicon, germanium, and/or silicon-germanium alloys. Heterostructures comprising group IV semiconductor materials may host 2DHGs.

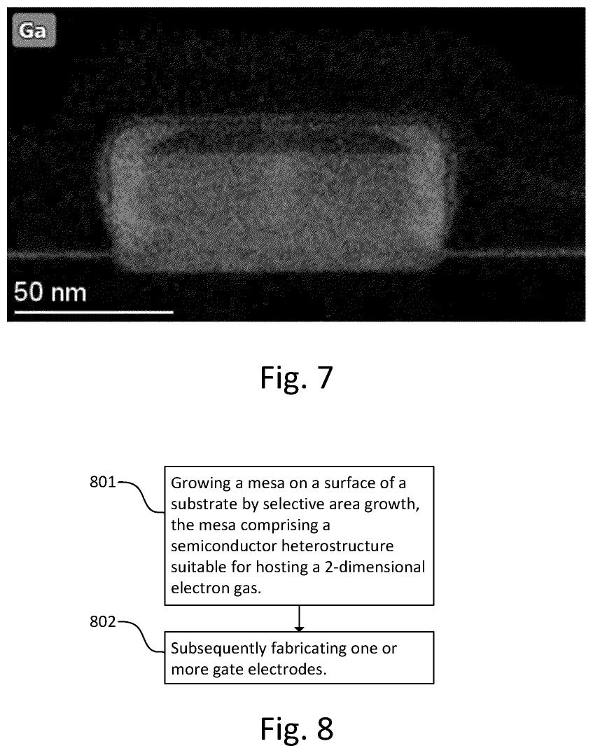

FIG. 7 is an elemental map showing the distribution of gallium in an example selective-area-grown semiconductor heterostructure. The brightness at a given position is proportional to the amount of gallium present at that position. As may be seen, regions at the left- and right-hand sides of the heterostructure have relatively high concentrations of gallium in comparison with the middle of the device. This illustrates that the distribution of elements in a semiconductor component may be inhomogeneous, with the edges of the device having a different composition to the middle of the device.

An example method for fabricating a semiconductor device will now be described with reference to FIG. 8. FIG. 8 is a flow chart outlining the method.

At block 801, a mesa comprising a semiconductor heterostructure suitable for hosting a 2DEG is grown on a surface of a substrate by selective area growth.

The substrate may be as described above with reference to FIG. 1. In particular, the substrate may be a wafer of indium phosphide.

The surface of the substrate may be a {111} crystal face, particularly in implementations where the device is to include a superconductor component. Crystals of superconductor materials such as aluminium have been found to grow particularly well on {111} faces.

Selective area growth includes forming a mask on the surface of the substrate. The mask has an opening which defines the location at which the mesa will grow. The mask may be formed by depositing a layer of mask material and then forming the opening by lithography and etching.

The mask may comprise any material which provides selectivity during growth, and in particular may comprise an amorphous dielectric material. Examples of dielectric materials useful for forming masks include silicon oxides, SiOₓ; silicon nitrites, SiNₓ; aluminium oxides, AlOₓ; and hafnium oxides, HfOₓ.

After forming the mask, the mesa is grown epitaxially on the surface of the substrate in the opening. Examples of useful techniques for growing semiconductor components include such as molecular beam epitaxy (“MBE”), metal-organic vapor phase epitaxy (“MOVPE”), and the like. Since the mesa comprises a heterostructure, layers of different materials are built up sequentially. For example, growing the mesa may comprise growing a lower barrier in the opening; growing a quantum well grown on the lower barrier; and growing an upper barrier on the quantum well.

The opening of the mask is configured such that the mesa is narrow, for example having a width of less than or equal to 2 μm. This allows for relaxation of strain in the grown crystal.

Optionally, after growing the semiconductor heterostructure, a superconductor component may be formed on the semiconductor heterostructure. This may comprise globally depositing a layer of superconductor material, and then patterning the layer to obtain the superconductor component, for example using a selective etch.

Alternatively, shadow walls may be used to control deposition of the superconductor material, as described in US 2020/0243742 A1. In such implementations, the shadow walls may be formed before growing the mesa on the substrate.

Optionally, a gate dielectric is deposited over the semiconductor heterostructure. In implementations where a superconductor component is formed, this operation may be performed after fabricating the superconductor component.

After growing the semiconductor heterostructure, at block 802, the one or more gate electrodes are fabricated. Any appropriate technique may be used to fabricate the gate electrodes.

For example, an electrode material may be globally deposited over the whole surface of the substrate, and then subsequently patterned to form the gate electrodes. Patterning the electrodes may comprise forming a mask over the electrode material, and then selectively etching portions of the electrode material. Another possibility is to use a lift-off process to pattern the gate electrodes.

Another possibility is to deposit electrode material selectively over desired portions of the substrate. The deposition may be controlled by the use of shadow walls, as described in e.g. US 2020/0243742 A1.

The method may include further steps as necessary, for example, connecting one or more portions of the device to further components.

In implementations where the device is to include a superconductor component which is not overlapped by the gate electrodes, such as the FIG. 2 device, the gate electrodes and superconductor component may be fabricated at the same time and from the same material.

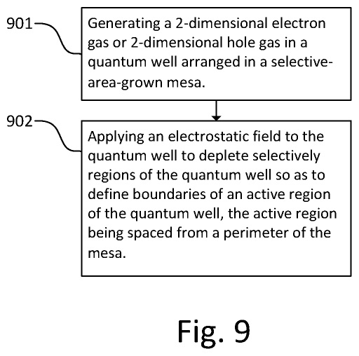

An example method of operating a semiconductor device is illustrated in FIG. 9. The semiconductor device may be a semiconductor device as described herein.

At block 901, a 2-dimensional electron gas or 2-dimensional hole gas is generated in a quantum well arranged in the selective-area-grown mesa.

At block 902, an electrostatic field is applied to the quantum well using the one or more gate electrodes, to deplete selectively regions of the quantum well so as to define boundaries of an active region of the quantum well, the active region being spaced from a perimeter of the mesa.

It will be appreciated that the above embodiments have been described by way of example only.

More generally, according to one aspect disclosed herein, there is provided a semiconductor device, comprising: a substrate having a surface; a mesa arranged on the surface of the substrate, the mesa having a perimeter; and one or more gate electrodes. The mesa is obtainable by selective area growth, and comprises a semiconductor heterostructure for hosting a 2-dimensional electron gas or a 2-dimensional hole gas. The one or more gate electrodes are configured to deplete electrically portions of the semiconductor heterostructure to define a boundary of an active region of the semiconductor heterostructure, the boundary being spaced from the perimeter of the mesa. It has been found that, by using a selective-area-grown mesa, it is made possible to obtain heterostructures from a wide range of combinations of materials, since relaxation of strain can occur towards the perimeter of the mesa during growth. By using electrostatic gating to define the border of the active region of the mesa, rather than relying on a material boundary, the electrical properties of the device may be improved by excluding from the active region inhomogeneous material close to the perimeter of the mesa.

Depending upon the selection of materials chosen, the semiconductor heterostructure may be configured to host a 2-dimensional electron gas or a 2-dimensional hole gas.

At least one of the gate electrodes may be arranged over a top surface of the mesa.

In such implementations, those regions of the semiconductor heterostructure which are under the electrodes are depleted when the gate electrodes apply an electrostatic field to the mesa.

At least one of the gate electrodes may be arranged on a side of the mesa. By adjusting the voltage applied to the one or more gate electrodes, material which is within a selectable distance from the gate electrodes may be electrically depleted.

The semiconductor heterostructure may comprise a quantum well arranged between a lower barrier and an upper barrier.

The mesa may have a width of less than or equal to 2 μm, and optionally less than or equal to 1 μm. There is no particular lower limit on the width of the mesa, provided that the gate electrodes can be fabricated with enough precision to define the boundaries of the active region. For example, the mesa may be at least 100 nm wide.

The boundary of the active region may be spaced from the perimeter of the mesa by at least 10 nm, optionally at least 25 nm. Strain relaxation during growth results in inhomogeneity of the composition of the materials close to the perimeter of the mesa. The spatial extent of the inhomogeneous region is generally small. A spacing of 10 nm or more may be effective for excluding all inhomogeneous material from the active region.

The semiconductor device may further comprise a superconductor component arranged over the active region. In other words, the semiconductor device may be a semiconductor-superconductor hybrid device. Such hybrid devices may be useful as components of topological quantum computers.

The surface of the substrate may be a {111} crystal face. The device may further include a superconductor component, and superconductor components grow particularly well on {111} crystal faces. Since the mesa is grown by selective area growth and since strain relaxation is possible, the mesa may be formed on a substrate having any desired crystal orientation.

In implementations where the device includes a superconductor component, at least one of the one or more gate electrodes may extend over the superconductor component. The semiconductor device may further comprise a gate dielectric arranged between the one or more gate electrodes and the superconductor component. In such implementations, the superconductor component may shield the active region from the electrostatic field applied by the at least one gate electrode. In a variant, a ferromagnetic metal component replaces the superconductor component.

The active region may be in the form of a nanowire. In other words, the active region may be an elongate region having a nano-scale width and a length-to-width ratio of at least 10, at least 100, or at least 500, or at least 1000. A nanowire typically has a width in the range to 500 nm, optionally 50 to 100 nm, 40 to 200 nm, or 75 to 125 nm. Nanowires can be treated as 1-dimensional systems, and may display interesting behaviour.

Alternatively, the active region may be a quantum dot having a boundary defined by the one or more gate electrodes. Quantum dots are useful in spin qubit devices.

The device may include a plurality of active regions, particularly in implementations where the active regions are quantum dots.

The device may include a ferromagnetic component. The ferromagnetic component may apply a magnetic field to an active region of the device. In particular, when the active region is a quantum dot, the device may include a ferromagnetic component.

At least one of the gate electrodes may be configured as a ferromagnetic component. In other words, at least one of the gate electrodes may comprise a ferromagnetic material. The ferromagnetic metal may be cobalt. By forming the one or more gate electrodes from a ferromagnetic material, the gate electrodes apply a magnetic field to the active region in addition to defining electrostatically the boundary of the active region.

Additionally or alternatively, the device may include a ferromagnetic component which is not a gate electrode.

The ferromagnetic component may comprise a ferromagnetic insulator component. In such implementations, the gate electrode typically does not overlap the ferromagnetic insulator component.

Alternatively, the ferromagnetic component may comprise a ferromagnetic metal and may be arranged between at least one of the gate electrodes and the active region. The ferromagnetic metal may screen the electric field applied by the gate from the active region in order to define a quantum dot, while at the same time applying a magnetic field to the quantum dot.

In implementations where the device includes two or more active regions, the ferromagnetic component may be configured to apply individually-selected magnetic fields to individual ones of the active regions. Two or more ferromagnetic components may be present. Each ferromagnetic component may be associated with a respective active region.

In another aspect, there is provided a qubit device comprising a plurality of the semiconductor devices provided herein. The qubit may be a topological qubit or a spin qubit.

In a still further aspect, there is provided a method of fabricating a semiconductor device. The method comprises: growing a mesa on a surface of a substrate by selective area growth, the mesa comprising a semiconductor heterostructure suitable for hosting a 2-dimensional electron gas or 2-dimensional hole gas; and subsequently fabricating one or more gate electrodes. The one or more gate electrodes are configured, when in use, to deplete electrically portions of the semiconductor heterostructure to define a boundary of an active region of the semiconductor heterostructure, the boundary being spaced from a perimeter of the mesa.

Selective area growth comprises forming a mask on the surface of the substrate, and growing semiconductor material in openings in the mask. The mask controls the location(s) at which the semiconductor material grows.

Growing the mesa may comprise growing a lower barrier on the surface of the substrate; subsequently growing a quantum well on the lower barrier; and subsequently growing an upper barrier over the quantum well.

The mesa may have a width of less than or equal to 2 μm, and optionally less than or equal to 1 μm. This may allow more effective relaxation of strain during growth of the semiconductor heterostructure.

The method may further comprise fabricating a superconductor component or ferromagnet. The superconductor component or ferromagnet may be fabricated after growing the mesa and before fabricating the one or more gate electrodes. The method may further comprise fabricating a gate dielectric covering the superconductor component or ferromagnet before fabricating the one or more gate electrodes. The one or more gate electrodes may be fabricated on the gate dielectric and over the superconductor component or ferromagnet. In implementations where a ferromagnet is fabricated before fabricating the one or more gate electrodes and the one or more gate electrodes extend over the ferromagnet, the ferromagnet comprises a ferromagnetic metal.

The one or more gate electrodes may be fabricated from a ferromagnetic material. The ferromagnetic material may be cobalt.

A still further aspect provides the use of one or more gate electrodes to define an active region of a semiconductor heterostructure by depleting electrically a boundary of the active region, wherein the semiconductor heterostructure is obtainable by selective area growth, and wherein the boundary is spaced from an edge of the semiconductor heterostructure. By defining the active area electrostatically, rather than relying on a physical, material boundary to bound the active region, electron transport properties of the active region may be improved. For example, diffuse scattering of charge carriers, e.g. electrons, may be avoided.

The use may be in the context of a device as defined herein.

The semiconductor heterostructure may have a width of less than or equal to 2 μm, optionally 1 μm.

The one or more gate electrodes may comprise a ferromagnetic material. In such implementations, the one or more gate electrodes are further used to apply a magnetic field to the active region.

A related aspect provides a method of operating a semiconductor device, in particular a semiconductor device as defined herein. The method includes: generating a 2-dimensional electron gas or 2-dimensional hole gas in a quantum well arranged in a selective-area-grown mesa; and applying an electrostatic field to the quantum well to deplete selectively regions of the quantum well so as to define boundaries of an active region of the quantum well, the active region being spaced from a perimeter of the mesa. By defining the boundaries of the active region electrostatically, rather than relying on the material boundary at the physical edge of the quantum well, charge transport properties may be improved. For example, diffuse scattering of electrons or holes due to disorder close to the material boundary may be avoided.

The mesa may be as described above. In particular, the mesa may have a width of less than or equal to 2 μm. By providing a narrow mesa, strain relaxation during growth of the mesa is made possible. Strain relaxation may allow a higher-quality crystal structure to be obtained. Strain relaxation may allow a wider range of combinations of materials to be used. Without wishing to be bound by theory, it is believed that a narrow mesa may allow the release of strain by geometric deformation. In traditional planar structures, strain is instead usually released by the creation of defects. The creation of defects limits significantly the amount of lattice mismatch traditional systems can tolerate.

The method may further comprise applying a magnetic field to at least the active region of the device. In such implementations, the electrostatic field may be applied using a gate electrode comprising a ferromagnetic material. In this way, the gate electrode may apply both the electrostatic field and the magnetic field.

The semiconductor device may include a superconductor component. In such implementations, the semiconductor device is operated at a temperate which is lower than the critical temperature of the superconductor component.

Other variants or use cases of the disclosed techniques may become apparent to the person skilled in the art once given the disclosure herein. The scope of the disclosure is not limited by the described embodiments but only by the accompanying claims.

1-15. (canceled)

16. A semiconductor device, comprising:
a substrate having a surface;
a mesa arranged on the surface of the substrate, the mesa having a perimeter; and
one or more gate electrodes;
wherein the mesa is obtainable by selective area growth, and comprises a semiconductor heterostructure for hosting a 2-dimensional electron gas or a 2-dimensional hole gas; and
wherein the one or more gate electrodes are configured to deplete electrically portions of the semiconductor heterostructure to define a boundary of an active region of the semiconductor heterostructure, the boundary being spaced from the perimeter of the mesa.

17. The semiconductor device according to claim 16, wherein the semiconductor heterostructure comprises a quantum well arranged between a lower barrier and an upper barrier.

18. The semiconductor device according to claim 16, wherein the mesa has a width of less than or equal to 2 μm.

19. The semiconductor device according to claim 16, wherein the boundary of the active region is spaced from the perimeter of the mesa by at least 10 nm.

20. The semiconductor device according to claim 16, wherein the surface of the substrate is a {111} crystal face.

21. The semiconductor device according to claim 16, further comprising a superconductor component arranged over the active region.

22. The semiconductor device according to claim 21, wherein at least one of the one or more gate electrodes extends over the superconductor component, and wherein the semiconductor device further comprises a gate dielectric arranged between the one or more gate electrodes and the superconductor component.

23. The semiconductor device according to claim 16, wherein the active region is in the form of a nanowire.

24. The semiconductor device according to claim 16, wherein the active region is in the form of a quantum dot.

25. The semiconductor device according to claim 16, comprising a ferromagnetic component.

26. The semiconductor device according to claim 25, wherein at least one of the one or more gate electrodes is a ferromagnetic component and comprises a ferromagnetic metal.

27. The semiconductor device according to claim 25, wherein the ferromagnetic component comprises a ferromagnetic metal and is arranged between at least one of the gate electrodes and the active region.

28. A method of fabricating a semiconductor device, the method comprising:
growing a mesa on a surface of a substrate by selective area growth, the mesa comprising a semiconductor heterostructure suitable for hosting a 2-dimensional electron gas or a 2-dimensional hole gas; and
subsequently fabricating one or more gate electrodes,
wherein the one or more gate electrodes are configured, when in use, to deplete electrically portions of the semiconductor heterostructure to define a boundary of an active region of the semiconductor heterostructure, the boundary being spaced from a perimeter of the mesa.

29. The method according to claim 28, wherein the growing the mesa comprises:
growing a lower barrier on the surface of the substrate;
subsequently growing a quantum well on the lower barrier; and
subsequently growing an upper barrier over the quantum well.

30. The method according to claim 28, wherein the mesa has a width of less than or equal to 2 μm.

31. The method according to claim 28, further comprising fabricating a superconductor component.

32. The method according to claim 31, wherein:
the superconductor component is fabricated after growing the mesa and before fabricating the one or more gate electrodes;
the method further comprises fabricating a gate dielectric covering the superconductor component before fabricating the one or more gate electrodes; and
the one or more gate electrodes are fabricated on the gate dielectric and over the superconductor component.

33. The method according to claim 28, further comprising fabricating a ferromagnetic component.

34. The method according to claim 33, wherein at least one of the one or more gate electrodes is fabricated from a ferromagnetic metal.

35. The method according to claim 28, further comprising:
forming a dielectric over the one or more gate electrodes; and
fabricating one or more further gate electrodes on the dielectric.
